(19) United States
(12) Patent Application Publication
(10) Pub. No.: US 2009/0137118 A1
(43) Pub. Date: May 28, 2009

(54) METHOD OF MANUFACTURING SEMICONDUCTOR DEVICE

(75) Inventors: Yusaku Hirota, Tokyo (JP); Itaru Kanno, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/248,450

(22) Filed: Oct. 9, 2008

(30) Foreign Application Priority Data
Nov. 22, 2007 (JP) 2007-303064 (P)
Aug. 11, 2008 (JP) 2008-207283 (P)

(51) Int. Cl. H01L 21/306; H01L 21/768

(52) U.S. Cl. 438/674; 134/2; 257/E21.585; 257/E21.228

(57) ABSTRACT

Initially, an interconnection 5w that contains copper is formed on a semiconductor substrate 1 (step (A)). On the interconnection 5w, an etching stopper film 6es is formed (step (B)). On the etching stopper film 6es, an insulating layer 6 is formed (step (C)). In the insulating layer 6, a via hole 6v that reaches the etching stopper film 6es is formed (step (D)). A surface of each of via hole 6v and the insulating layer 6 is cleaned with an organic solvent C (step (E)). The etching stopper film 6es is removed such that the interconnection 5w is exposed (step (F)). An interconnection 6w that electrically connects to the exposed interconnection 5w is further formed (step (G)). It is thereby possible to obtain a method of manufacturing a semiconductor device, including a cleaning step that can suppress corrosion of an interconnection that contains copper.

### BACKGROUND OF THE INVENTION

1. Field of the Invention

The present invention relates to a method of manufacturing a semiconductor device, and particularly relates to a method of manufacturing a semiconductor device, including a cleaning step after formation of a via hole.

2. Description of the Background Art

Steps of manufacturing a semiconductor device can broadly be classified into an FEOL (Front End Of Line) in which a semiconductor element such as a transistor is formed, and a BEOL (Back End Of Line) in which a multilayer metal interconnection is formed thereon. In any group of steps in the FEOL and the BEOL, steps such as film formation, photolithography, and dry etching are repeated to thereby form patterns. In each of these steps, contaminants such as particles, organic substances, and metal adhere to a surface of a wafer formed of a substrate and a multilayer interconnection. To improve yields of semiconductor devices, a cleaning step for removing contaminants on the wafer surface is required.

In the above-described cleaning step, there is performed chemical cleaning that removes contaminants by a chemical reaction caused by a chemical solution such as an acid or an alkali, physical cleaning that removes contaminants by using physical force such as ultrasound, or combination cleaning of chemical cleaning and physical cleaning. An optimal cleaning method is selected depending upon a step in which cleaning is to be performed, or contaminants to be targeted. In any cleaning method, pure water is usually used for flushing a chemical solution from the wafer surface, or for final cleaning prior to drying. Further, the chemical solution is diluted with pure water to a prescribed concentration and used. In other words, pure water is used as a solvating medium for cleaning a wafer in most cases.

In recent years, when the wafer surface is to be cleaned with the use of such a pure water solvating medium, ultrasonic cleaning, two-fluid jet cleaning, and the like have been used to improve cleaning effects (e.g. see Japanese Patent Laying-Open No. 2005-005469). Here, the ultrasonic cleaning is identified as a cleaning method in which a chemical solution containing a pure water solvating medium to which ultrasound is applied, is brought into contact with the wafer surface. The two-fluid jet cleaning is identified as a cleaning method in which a pure water solvating medium (usually, pure water alone) and a spray gas are mixed in a nozzle and sprayed onto the wafer surface. In general, such two-fluid jet cleaning only uses pure water at room temperature (e.g. at 25° C.) and a spray gas, and hence offers major cost benefits. Further, physical cleaning force can be controlled by a flow rate of the spray gas, and hence damages to the wafer can be reduced.

Here, in the BEOL for the latest semiconductor device, an interconnection that contains copper is used. As a process of forming such an interconnection that contains copper, there is widely used a so-called dual damascene process in which a via hole and an interconnection groove (trench) are formed in an insulating layer, a metal material that contains copper is then embedded in the via hole and the interconnection groove by plating, and furthermore, planarization is performed by CMP (chemical mechanical polishing). When the via hole is formed in the insulating layer by dry etching and ashing, the etching is usually stopped by an etching stopper film formed in advance on an underlying interconnection.

In recent years, however, a low-dielectric constant (Low-k) material has been demanded for an interlayer insulating layer for such an interconnection structure that contains copper. Such a Low-k material has a low density to lower a k value (dielectric constant value). Therefore, dry etching and ashing carried out in forming the via hole tend to form in the etching stopper film a pinhole that reaches the interconnection underlying the etching stopper film. The inventors of the present invention have found that, when the cleaning process that uses a pure water solvating medium is performed in the state where a pinhole is formed in the etching stopper film, as described above, a portion of the interconnection that contains copper, which is formed under the etching stopper film located at a bottom of the via hole, is subjected to corrosion, resulting in a cavity.

On the other hand, if the cleaning step with the use of a water solvating medium is eliminated, contaminants remain on the wafer, causing decrease in manufacturing yields of semiconductor devices. It is possible to prevent the generation of a pinhole by increasing a thickness of the etching stopper film or increasing a density of the insulating layer. However, a k value is inevitably increased.

Examples of cleaning that does not use a pure water solvating medium include dry-ice cleaning, aerosol cleaning, and the like. Here, the dry-ice cleaning refers to a cleaning method in which solid carbon dioxide generated by spraying liquid carbon dioxide through a one-fluid nozzle and fine particles of liquid carbon dioxide are made to impinge upon the wafer surface. The aerosol cleaning refers to a cleaning method in which solid particles obtained by cooling argon and nitrogen to the freezing point or lower are sprayed onto the wafer surface. However, the problem is that these methods are expensive in device cost and running cost.

### SUMMARY OF THE INVENTION

The present invention has been made in view of the above-described problems. An object of the present invention is to provide a method of manufacturing a semiconductor device, including a cleaning step that does not cause corrosion of an interconnection that contains copper and underlies an etching stopper film, even if a pinhole is formed in the etching stopper film during a via hole forming step.

The method of manufacturing the semiconductor device in the present embodiment includes:

a step (A) of forming on a semiconductor substrate a first interconnection which contains copper; a step (B) of forming an etching stopper film on the first interconnection; a step (C) of forming an insulating layer on the etching stopper film; a step (D) of forming in the insulating layer a via hole which reaches the etching stopper film; a step (F) of removing the etching stopper film such that the via hole reaches the first interconnection and that the first interconnection is exposed through the via hole; and a step (E) of cleaning a surface of each of the via hole and the insulating layer with an organic solvent before the above-described step (F).

According to the method of manufacturing the semiconductor device in the present embodiment, a surface of each of the via hole and the insulating layer is cleaned with the organic solvent. Therefore, even if a pinhole is formed in the etching stopper film in the via hole forming step, corrosion of the first interconnection, which underlies the etching stopper film, is suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart that shows a method of manufacturing a semiconductor device in Embodiment 1 of the present invention.

FIG. 2 is a schematic cross-sectional view that shows a first step of the method of manufacturing the semiconductor device in Embodiment 1 of the present invention, and shows a step (A).

FIG. 3 is a schematic cross-sectional view that shows a second step of the method of manufacturing the semiconductor device in Embodiment 1 of the present invention, and shows a step (B).

FIG. 4 is a schematic cross-sectional view that shows a third step of the method of manufacturing the semiconductor device in Embodiment 1 of the present invention, and shows a step (C).

FIG. 5 is a schematic cross-sectional view that shows a fourth step of the method of manufacturing the semiconductor device in Embodiment 1 of the present invention, and shows a step (D).

FIG. 6 is a schematic cross-sectional view that shows a fifth step of the method of manufacturing the semiconductor device in Embodiment 1 of the present invention, and shows a step (E1).

FIG. 7 is a schematic cross-sectional view that shows a sixth step of the method of manufacturing the semiconductor device in Embodiment 1 of the present invention, and shows a step (F).

FIG. 8 is a schematic cross-sectional view that shows a seventh step of the method of manufacturing the semiconductor device in Embodiment 1 of the present invention.

FIG. 9 is a schematic cross-sectional view that shows an eighth step of the method of manufacturing the semiconductor device in Embodiment 1 of the present invention, and shows a step (G).

FIG. 10 is a schematic cross-sectional view that shows a first step of a method of manufacturing a semiconductor device in Embodiment 2 of the present invention, and shows a step (H).

FIG. 11 is a schematic cross-sectional view that shows a second step of the method of manufacturing the semiconductor device in Embodiment 2 of the present invention, and shows a step (E2).

FIG. 12 is a schematic cross-sectional view that shows a third step of the method of manufacturing the semiconductor device in Embodiment 2 of the present invention, and shows a step (F).

FIG. 13 is a schematic cross-sectional view that shows a fourth step of the method of manufacturing the semiconductor device in Embodiment 2 of the present invention.

FIG. 14 is a schematic cross-sectional view that shows a fifth step of the method of manufacturing the semiconductor device in Embodiment 2 of the present invention, and shows a step (G).

FIG. 15 is a schematic cross-sectional view that shows a method of manufacturing a semiconductor device in Embodiment 4 of the present invention, and shows a step (J1).

FIG. 16 is a schematic cross-sectional view that shows a method of manufacturing a semiconductor device in Embodiment 5 of the present invention, and shows a step (J2).

FIG. 17 is a cross-sectional view that schematically shows a configuration of a semiconductor device that has an interconnection with a multilayer structure.

FIG. 18A is a schematic cross-sectional view for describing the problems in a cleaning process that uses a pure water solvating medium, and shows a step of forming a via hole.

FIG. 18B is a drawing that shows a cleaning step that uses a pure water solvating medium.

FIG. 19 is a schematic view that shows one embodiment of a two-fluid jet cleaning device.

FIG. 20 is a schematic view that shows one embodiment of an ultrasonic fluid cleaning device.

FIG. 21 is a schematic view that shows one embodiment of an ultrasonic immersion cleaning device.

FIG. 22 is a schematic view that shows another embodiment of the ultrasonic immersion cleaning device.

FIG. 23 is a diagram that shows the number of corrosion sites of a copper interconnection in each of two-fluid jet cleaning that uses a pure water solvating medium and two-fluid jet cleaning that uses an organic solvent.

FIG. 24A is a micrograph showing that, among portions of the copper interconnection exposed through a plurality of pinholes, respectively, only the portion exposed through one pinhole is subjected to corrosion.

FIG. 24B is a micrograph that shows in an enlarged manner the portion subjected to corrosion in FIG. 24A.

FIG. 25 is a diagram that shows the results of measurement of temperatures at a central portion and an outer peripheral portion of the wafer during cleaning.

### DESCRIPTION OF THE PREFERRED EMBODIMENTS

Embodiments of the present invention will hereinafter be described based on the drawings.

### Embodiment 1

Initially, a method of manufacturing a semiconductor device in the present embodiment will be described schematically.

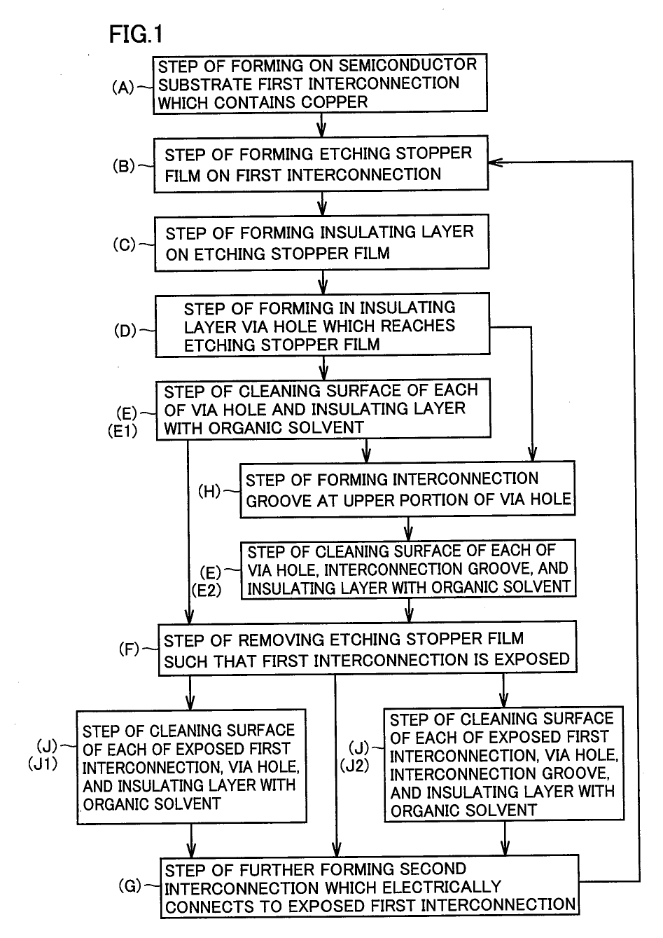

With reference to FIG. 1, in the method of manufacturing the semiconductor device in the present embodiment, a first interconnection that contains copper is initially formed on a semiconductor substrate (a step (A)). On the first interconnection, an etching stopper film is formed (a step (B)). On the etching stopper film, an insulating layer is formed (a step (C)). In the insulating layer, a via hole that reaches the etching stopper film is formed (a step (D)). A surface of each of the via hole and the insulating layer is cleaned with an organic solvent (a step (E)). The etching stopper film is removed such that the via hole reaches the first interconnection and that the first interconnection is exposed through the via hole (a step (F)). A second interconnection that electrically connects to the exposed first interconnection is formed (a step (G)).

In the above-described manufacturing method, step (E) of cleaning the surface of each of the via hole and the insulating layer is performed before step (F) of removing the etching stopper film such that the first interconnection is exposed through the via hole.

Next, the above-described manufacturing method will specifically be described with the use of cross-sectional views of the semiconductor device.

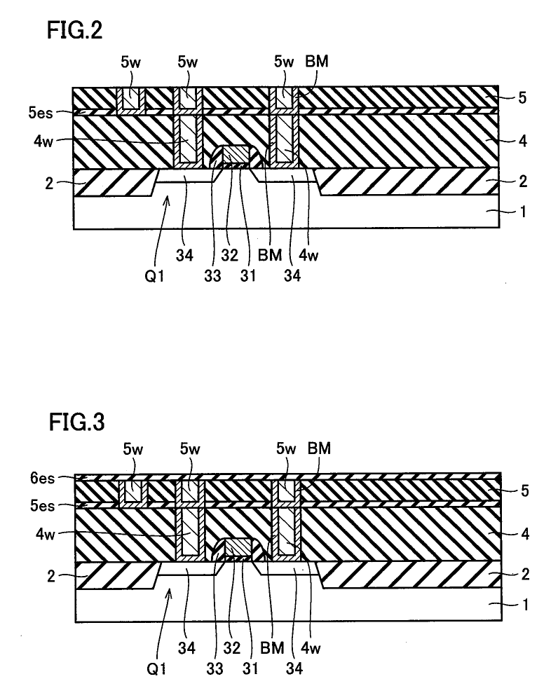

With reference to FIG. 2, the step of forming on a semiconductor substrate 1 an interconnection 5w that contains copper (step (A)) is performed, for example, as follows.

Initially, on semiconductor substrate 1, a MOS transistor Q1 is disposed in an active region defined by an element isolation insulating film 2. Here, MOS transistor Q1 has a pair of source and drain regions 34 formed at a surface of semiconductor substrate 1, and a gate electrode 32 disposed on a region of semiconductor substrate 1 located between the pair of source and drain regions 34, with a gate oxide film 31 interposed between semiconductor substrate 1 and gate electrode 32. Further, a sidewall insulating film 33 is disposed on each of opposite sides of gate electrode 32.

Next, an insulating layer 4 is formed on semiconductor substrate 1 to cover MOS transistor Q1. Contact holes that penetrate insulating layer 4 and reach source and drain regions 34, respectively, are formed. In the contact holes, interconnections 4w that contain copper are formed to electrically connect to source and drain regions 34, respectively.

Next, on interconnection 4w, an etching stopper film 5es and an insulating layer 5 are successively formed. A groove that penetrates insulating layer 5 and etching stopper film 5es is formed, and in this groove, an interconnection 5w that contains copper is formed to electrically connect to interconnection 4w (step (A)).

It is noted that, from a viewpoint of suppressing migration of the interconnection, a barrier metal layer BM is preferably formed between interconnection 4w and insulating layer 4, and between interconnection 5w and insulating layer 5. From such a viewpoint, the barrier metal layer preferably contains at least one material selected from the group consisting of Ta, Ti, W, and Ru.

With reference to FIG. 3, an etching stopper film 6es is formed on interconnection 5w (step (B)).

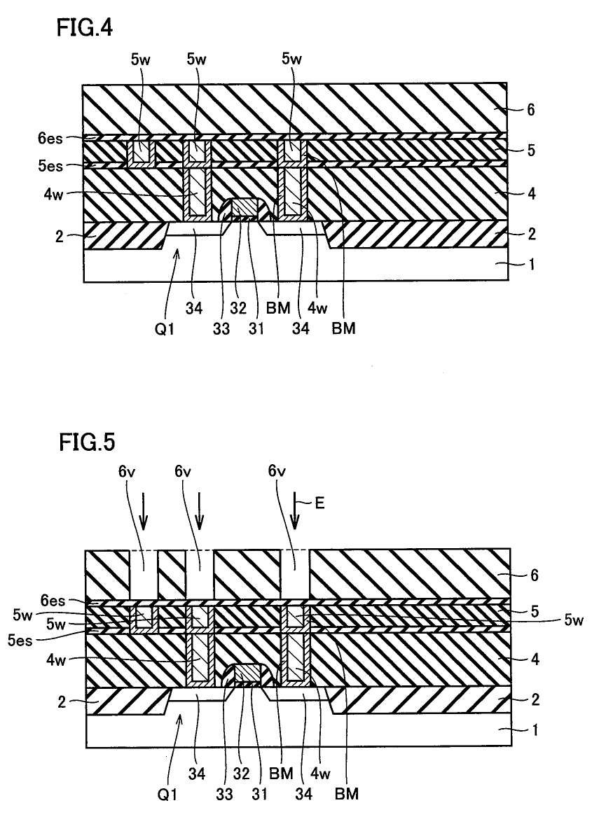

With reference to FIG. 4, an insulating layer 6 is formed on etching stopper film 6es (step (C)).

With reference to FIG. 5, a via hole 6v that reaches etching stopper film 6es is formed in insulating layer 6 (step (D)). A method of forming via hole 6v is not particularly limited. However, from a viewpoint of facilitating formation of minute via hole 6v, dry etching E is preferable. Owing to such dry etching E, contaminants such as etching residues adhere to a surface of each of via hole 6v and insulating layer 6.

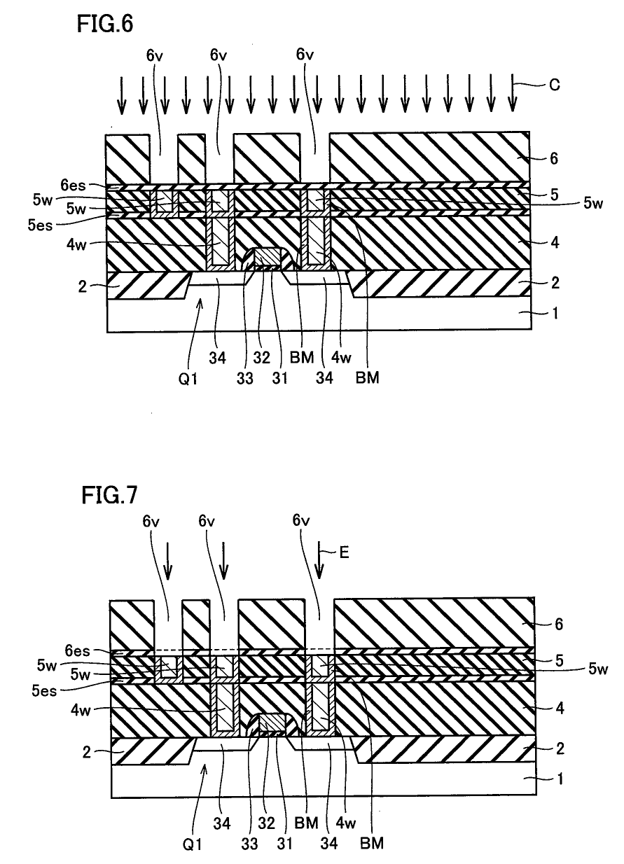

With reference to FIG. 6, the surface of each of via hole 6v and insulating layer 6 is cleaned with an organic solvent C (step (E)). Organic solvent C is preferably hydrofluoroether. Particularly, organic solvent C is preferably HFE7100 (having a chemical formula of C₄F₉OCH₃, a boiling point of 61° C., and a solubility of water (which hereinafter refers to a solubility of water in organic solvent C) of 95 ppm (by mass)), HFE7200 (having a chemical formula of C₄F₉OC₂H₅, a boiling point of 76° C., and a solubility of water of 92 ppm (by mass)), or HFE7300 (a chemical formula of C₆F₁₃OCH₃, a boiling point of 98° C., and a solubility of water of 67 ppm (by mass)), among hydrofluoroethers.

Further, the organic solvent is preferably a solvent having a boiling point of at least 98° C., and preferably a solvent having a solubility of water of at most 67 ppm by mass.

With reference to FIG. 7, etching stopper film 6es is removed such that via hole 6v reaches interconnection 5w and that interconnection 5w is exposed through via hole 6v (step (F)). A method of removing etching stopper film 6es is not particularly limited. However, from a viewpoint of facilitating formation of minute via hole 6v, dry etching E is preferable.

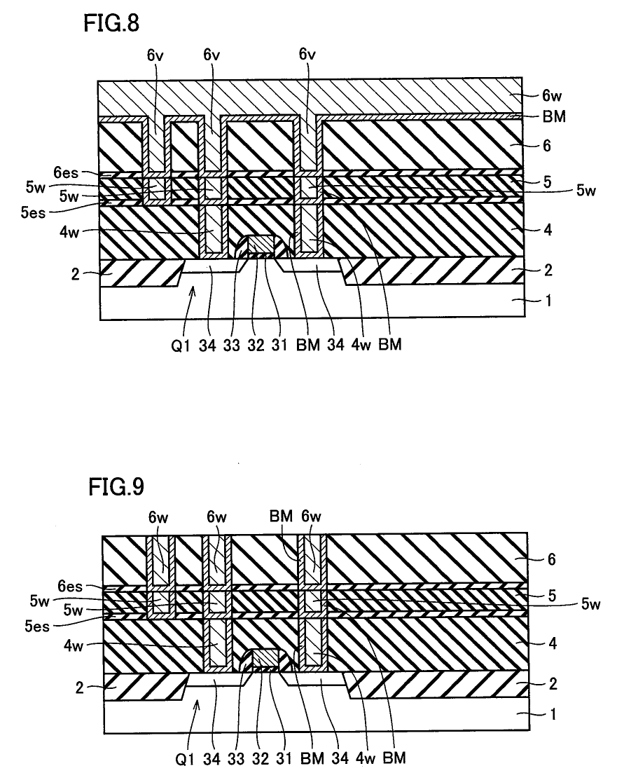

With reference to FIG. 8, a conductive layer 6w made of a material containing copper is formed on insulating layer 6 such that conductive layer 6w is embedded in via hole 6v by plating. Subsequently, conductive layer 6w is removed by a CMP (Chemical Mechanical Polishing) method until a top surface of insulating layer 6 is exposed.

It is noted that, from a viewpoint of suppressing migration of the interconnection, barrier metal layer BM is preferably formed between conductive layer 6w and insulating layer 6. In the case where barrier metal layer BM is formed, when the above-described CMP method is performed, barrier metal layer BM located on the top surface of insulating layer 6 is removed by the CMP method, resulting in that the top surface of insulating layer 6 is exposed.

With reference to FIG. 9, by the above-described CMP method, conductive layer 6w remains in via hole 6v. Thereby interconnection 6w that is electrically connected to interconnection 5w is formed from conductive layer 6w (step (G)).

As described above, the semiconductor device according to the present embodiment is manufactured.

It is noted that, in the description above, each of interconnections 4w, 5w, 6w that contain copper is made of a material that contains 99% copper by mass, for example, and further contains light elements (S, O, Cl, C, N, and the like). Further, etching stopper films 5es, 6es preferably contain at least one material selected from the group consisting of SiCN, SiCO, SiC, and SiN from a viewpoint of reliably stopping etching of insulating layers 5, 6, respectively. Further, each of etching stopper films 5es, 6es is preferably made of a stacked-layer structure in which an SiCN film (with a thickness of 30 nm) and an SiCO film (with a thickness of 30 nm), for example, are successively stacked from underneath. Further, each of insulating layers 4, 5, 6 preferably contains at least one Low-k material selected from the group consisting of TEOS (tetraethoxysilane), SiOF, and SiOC from a viewpoint of lowering a dielectric constant. Each of insulating layers 4, 5, 6 preferably has a dielectric constant of at most 3.

Next, functional effects of the present embodiment will be described.

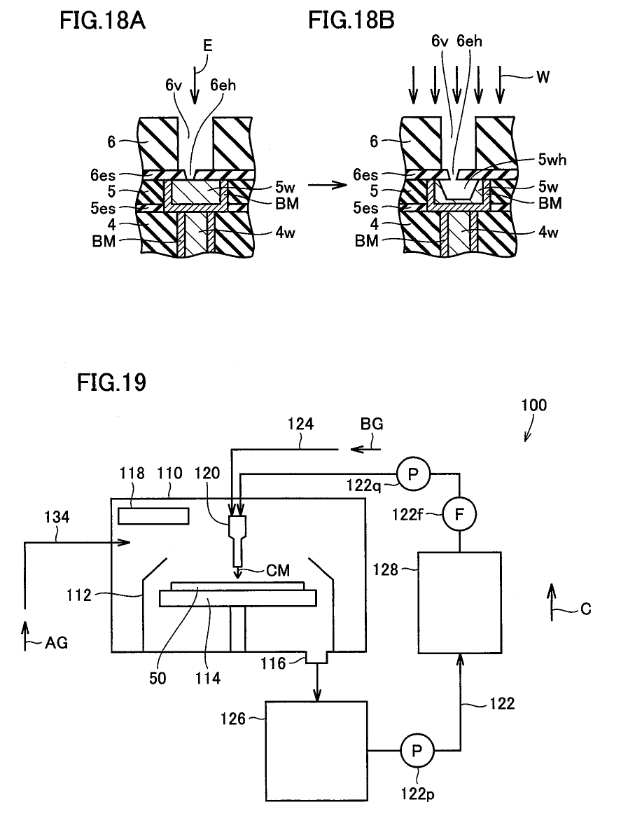

FIG. 18A is a schematic cross-sectional view that shows how a pinhole is generated in the etching stopper film on the interconnection when the via hole is formed. FIG. 18B is a schematic cross-sectional view that shows a state in which a pure water solvating medium is used to clean the wafer surface, with a pinhole formed in the etching stopper film.

With reference to FIG. 18A, owing to dry etching E or the like for forming via hole 6v that reaches etching stopper film 6es in the above-described step (D) (FIG. 5), a pinhole 6eh that reaches interconnection 5w that underlies etching stopper film 6es tends to be formed in etching stopper film 6es.

With reference to FIG. 18B, the inventors of the present invention have found that, if a pure water solvating medium W is used to clean the wafer surface with pinhole 6eh formed, interconnection 5w that contains copper, which underlies via hole 6v, is subjected to corrosion, resulting in a cavity 5wh. The cavity generated by such corrosion of interconnection 5w causes poor connection of the interconnection.

In contrast, in step (E) shown in FIG. 6 of the present embodiment, the cleaning process that uses organic solvent C is performed. The inventors of the present invention have found that, if organic solvent C is used in the cleaning process as described above, it is possible to suppress in step (E) corrosion of interconnection 5w that contains copper and underlies etching stopper film 6es, even if pinhole 6eh is formed in etching stopper film 6es in step (D). Organic solvent C is used to perform the cleaning process in the present embodiment, and hence it is thereby possible to clean the surface of each of via hole 6v and insulating layer 6 and remove contaminants adhering to the surface thereof, while further suppressing corrosion of interconnection 5w that contains copper, when compared with the case where a pure water solvating medium is used.

Next, there will be described the details of experiments conducted by the inventors of the present invention to obtain the above-described findings, and the results thereof.

Initially, the inventors of the present invention performed cleaning that used a pure water solvating medium and cleaning that used an organic solvent (HFE7100, HFE7300), under the state where a layer having a pinhole was formed on a copper interconnection. The layer that had a pinhole had a stacked structure in which an SiCN film (with a thickness of 30 nm) and an SiCO film (with a thickness of 30 nm) were successively stacked from underneath. Each of the cleaning was performed by two-fluid jet cleaning. The cleaning conditions for the two-fluid jet cleaning were set as follows.
Processing time: 20 seconds
Wafer rotation number: 100 rpm
N₂ flow rate: 33.9 NL/min
Solvent (pure water or HFE) flow rate: 150 mL/min
Two-fluid nozzle scanning speed: 2.5 mm/sec

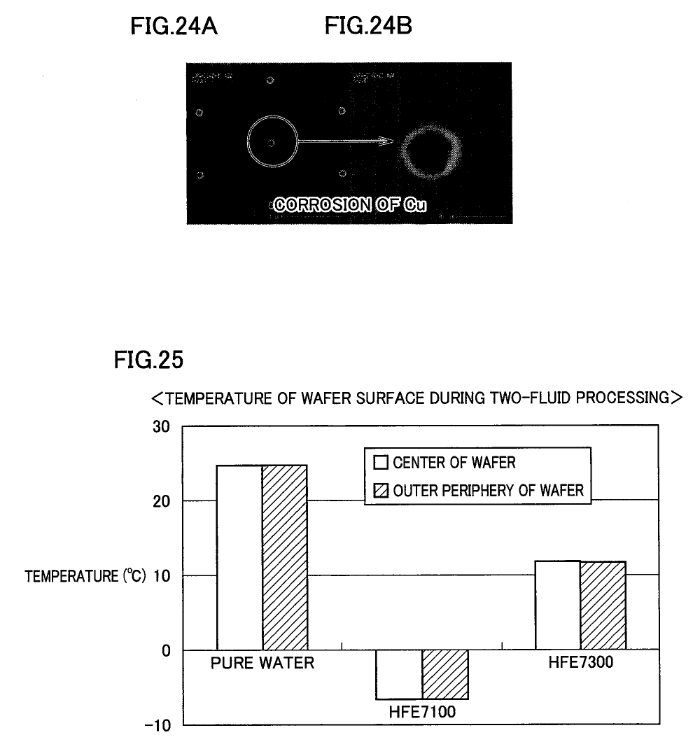

The results of the above-described cleanings are shown in FIG. 23 and FIGS. 24A and 24B.

According to the results in FIG. 23, in any of three experiments on the two-fluid jet cleaning that used a pure water solvating medium, the number of corrosion sites of the copper interconnection reached 80 or more, which was a relatively large number. In contrast, in any of the experiments on the two-fluid jet cleaning that used an organic solvent (HFE7100, HFE7300), the number of corrosion sites of the copper interconnection was at most 20, and hence the number of corrosion sites of the copper interconnection was significantly reduced when compared with the case where a pure water solvating medium was used. It is thereby found that the cleaning that uses an organic solvent can further suppress corrosion of the copper interconnection when compared with the cleaning that uses a pure water solvating medium.

The reason why such corrosion occurs is estimated as follows. Static electricity is built up at the surface of the wafer during cleaning, and causes electric field concentration at the pinhole portion, so that water is thereby ionized to generate hydrogen ions, which promote corrosion of copper exposed through the pinhole.

In view of the foregoing, it can be considered that the organic solvent was able to suppress corrosion of the copper interconnection because it contained a smaller amount of water than the pure water solvating medium did. Here, HFE7100 used in the above-described experiments has a solubility of water of 95 ppm (by mass), and HFE7300 used in the above-described experiments has a solubility of water of 67 ppm (by mass). It can be considered that HFE7300 has a solubility of water of 67 ppm (by mass), as described above, which is lower than that of HFE7100, and hence was able to further suppress corrosion of the copper interconnection. Therefore, to further suppress corrosion of the copper interconnection, the organic solvent preferably has a solubility of water of at most 67 ppm (by mass).

Determination as to whether corrosion had occurred or not was made by visually inspecting, under a microscope, the differences in color of the copper interconnection exposed through via holes, as shown in FIG. 24A and FIG. 24B. In other words, copper is oxidized through corrosion and turns into copper oxide with its color turning black, and hence whether corrosion had occurred or not was based on determination as to whether the color of the copper interconnection exposed through via holes was black (as in a via hole at the central portion in FIG. 24A) or not.

Next, the inventors of the present invention measured the temperatures of the central portion and the outer peripheral portion of the wafer during the above-described cleanings. FIG. 25 shows the results thereof.

According to the results in FIG. 25, the temperature of the wafer during the cleaning that used a pure water solvating medium was approximately 25° C. at any of the central portion and the outer peripheral portion. When HFE7300 was used, the temperature of the wafer was 111° C. to 13° C. at any of the central portion and the outer peripheral portion. When HFE7100 was used, the temperature of the wafer was −5° C. to −7° C. at any of the central portion and the outer peripheral portion.

When water or an organic solvent is sprayed through a nozzle for cleaning, the water or organic solvent evaporates, and resultant heat of vaporization cools an inside of the enclosed cleaning chamber. Dew condensation may occur thereby at the surface of each of the via hole and the insulating layer of the wafer, and water may be generated.

Here, HFE7100 has a boiling point of 61° C., which is lower than 98° C., namely, a boiling point of HFE7300. Therefore, it is considered that HFE7100 is more likely to evaporate than HFE7300 does, and hence owing to its heat of vaporization, lowered the temperature of the wafer surface when compared with the case where HFE7300 was used.

Further, in general, a dew point in the clean room is approximately 9° C. Therefore, it is considered that HFE7100, which causes a wafer surface temperature lower than the dew point (approximately 9° C.), is more likely to cause dew condensation at the surface of each of the via hole and the insulating layer of the wafer, so that water is more likely to be generated and corrosion of the copper interconnection is more likely to occur. Therefore, to further suppress corrosion of the copper interconnection, the organic solvent preferably has a boiling point of at least 98° C., which is a boiling point of HFE7300.

The cleaning step with the use of an organic solvent in step (E) in the present embodiment is not particularly limited. However, from a viewpoint of effectively removing contaminants adhering to the surface of each of the insulating layer 6, via hole 6v, interconnection groove 6t, exposed interconnection 5w, and the like, a cleaning method described in Embodiments 1A-1C below is preferably carried out.

### Embodiment 1A

With reference to FIG. 19, step (E) in Embodiment 1 is preferably performed by two-fluid jet cleaning in which organic solvent C and a spray gas BG are mixed in a nozzle 120 and sprayed onto the surface of each of the via hole and the insulating layer.

With reference to FIG. 19, a two-fluid jet cleaning device 100 for performing the above-described cleaning includes nozzle 120 for mixing two fluids, in an enclosed cleaning chamber 110. Nozzle 120 includes a spray gas line 124 for supplying spray gas BG, and a solvent circulation line 122 for recovering organic solvent C used for cleaning and supplying the same. Solvent circulation line 122 is provided with a solvent tank 126, a solvent refining unit 128, a filter 122f, and pumps 122p, 122q. Enclosed cleaning chamber 110 has a cleaning cup 112 provided therein. In cleaning cup 112, a stage 114 is provided for holding and rotating a wafer 50 on which a via hole and an insulating layer are formed. Cleaning cup 112 further has a solvent recovery port 116 for recovering a used solvent. In enclosed cleaning chamber 110, a static eliminating device 118 such as a discharge device, a soft X-ray radiation device, an ionizer, and an ultraviolet-ray radiation device is further provided. Enclosed cleaning chamber 110 further includes a dew condensation prevention gas line 134 for supplying a dew condensation prevention gas AG to itself.

With reference to FIG. 19, the two-fluid jet cleaning in the present embodiment is performed, for example, as follows. Initially, wafer 50 having a via hole and an insulating layer formed thereon, which is obtained after completion of step (D), is fixed onto stage 114 and rotated. Spray gas BG and organic solvent C are supplied to nozzle 120 for mixing two fluids, to generate fine mists CM of organic solvent C at nozzle 120. Mists CM are sprayed onto the surface of each of the via hole and the insulating layer of wafer 50. Spray gas BG and organic solvent C may be mixed by any of a technique of performing mixing inside nozzle 120 (an internally mixed type) and a technique of performing mixing outside nozzle 120 (an externally mixed type). Here, the spray gas is not particularly limited as long as it enables mists to be generated and sprayed. However, from a viewpoint of preventing intrusion of moisture, dry air, a nitrogen gas, or the like is preferably used. As such, contaminants adhering to the surface of each of the via hole and the insulating layer by step (D) and the like are removed.

Here, used organic solvent C in enclosed cleaning chamber 110 is recovered from solvent recovery port 116 in cleaning cup 112 to solvent tank 126. Organic solvent C recovered in solvent tank 126 is refined in solvent refining unit 128 by removing contaminants. Refined organic solvent C is further filtered through filter 122f, supplied again to nozzle 120, and used for the next wafer cleaning.

If cleaning is performed with the wafer rotated as in the present Embodiment 1A, electrification due to static electricity may occur. Therefore, it is preferable that static eliminating device 118 prevents the occurrence of electrification due to static electricity.

When organic solvent C is sprayed through nozzle 120, organic solvent C evaporates, and heat of vaporization of organic solvent C cools an inside of enclosed cleaning chamber 110. Dew condensation may thereby occur at the surface of each of the via hole and the insulating layer of wafer 50, and water may be generated. In such a case, if a pinhole is formed in the etching stopper film located at the bottom of the via hole, the underlying interconnection that contains copper may be subjected to corrosion.

Therefore, to prevent dew condensation at the surface of each of the via hole and the insulating layer of wafer 50, it is preferable that dew condensation prevention gas AG is supplied to enclosed cleaning chamber 110. Here, the dew condensation prevention gas is not particularly limited as long as it can prevent dew condensation at the surface of each of the via hole and the insulating layer. A gas having a low dew point, such as dry air or a nitrogen gas, is preferably used. Further, to prevent dew condensation, it is preferable that cleaning is performed in a nitrogen atmosphere in enclosed chamber 110 by purging at least any of dry air and a nitrogen gas.

Here, organic solvent C used in the two-fluid jet cleaning as in the present Embodiment 1A is preferably a solvent that has a solubility of water of at most 2% by mass, a boiling point of at least 80° C., a vapor pressure of at most 0.01 MPa, heat of evaporation of at most 120 kJ/kg, a density of at least 1 g/cm³, a surface tension of at most 72.8 mN/m at 20° C. and at 1013 hPa, a solubility of gas (which hereinafter refers to a solubility of gas in organic solvent C) higher than the solubility of water, and no flash point. Each of the properties will now be described.

(α1) Organic solvent C having a solubility of water of at most 2% by mass is preferable. By using organic solvent C having a solubility of water of at most 2% by mass, it is possible to effectively suppress corrosion of the interconnection that contains copper.

(α2) Organic solvent C that has a boiling point of at least 80° C., a vapor pressure of at most 0.01 MPa, heat of evaporation of at most 120 kJ/kg, and is less likely to evaporate is preferable. If organic solvent C evaporates during cleaning, heat of vaporization generated upon evaporation cools an inside of enclosed cleaning chamber 110, so that dew condensation may occur at the surface of each of the via hole and the insulating layer of wafer 50 and water may be generated. In such a case, if a pinhole is formed in the etching stopper film located at the bottom of the via hole, the underlying interconnection that contains copper may be subjected to corrosion. Therefore, by using an organic solvent that is less likely to evaporate, it is possible to prevent dew condensation at the surface of each of the via hole and the insulating layer of wafer 50.

(α3) Organic solvent C having a density of at least 1 g/cm³ is preferable. By increasing the density of organic solvent C and its mists, cleaning capacity can be improved.

(α4) Organic solvent C having a surface tension of at most 72.8 mN/m at 20° C. and at 1013 hPa is preferable. A lower surface tension produces finer mists, and higher fineness of generated mists leads to increase in amount of generated mists, so that cleaning capacity is improved.

(α5) Organic solvent C having a solubility of gas higher than the solubility of water is preferable. A higher gas concentration in organic solvent C causes higher foaming effect produced by the gas, and leads to increase in number of generated mists, so that cleaning capacity is improved.

(α6) Organic solvent C having no flash point is preferable from a viewpoint of safety.

An example of organic solvent C that has the properties (α1) to (α6) described above includes HFE (hydrofluoroether) such as C₆F₁₃OCH₃.

### Embodiment 1B

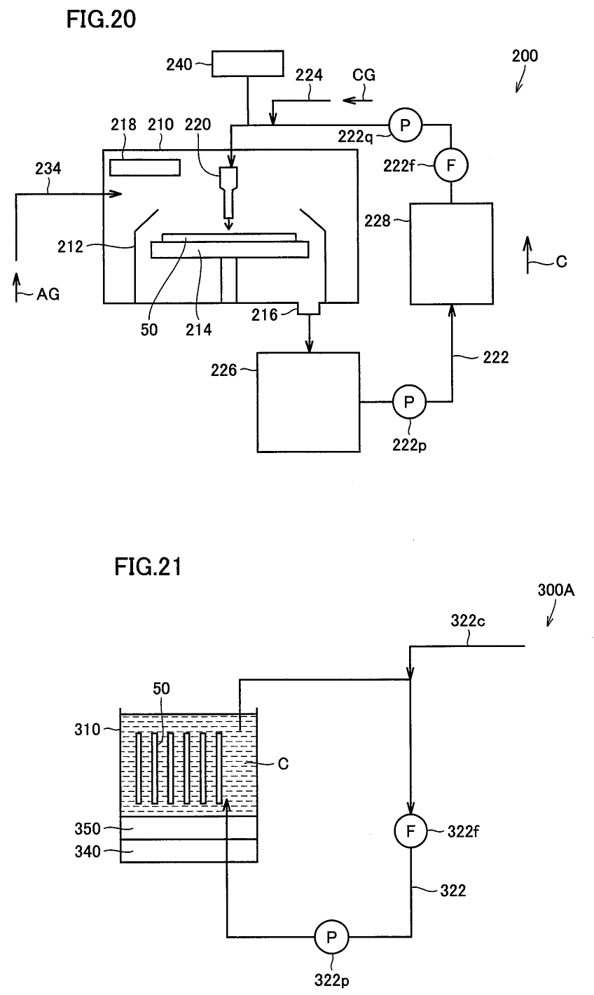

With reference to FIG. 20, step (E) in Embodiment 1 is preferably performed by single-wafer, nozzle injection-type, ultrasonic cleaning in which organic solvent C to which ultrasound is applied is sprayed onto the surface of each of the via hole and the insulating layer.

With reference to FIG. 20, a single-wafer, nozzle injection-type, ultrasonic cleaning device 200 for performing the above-described cleaning includes a nozzle 220 in an enclosed cleaning chamber 210. Nozzle 220 includes a solvent circulation line 222 for recovering organic solvent C used for cleaning and supplying the same. Solvent circulation line 222 is provided with a solvent tank 226, a solvent refining unit 228, a filter 222f, and pumps 222p, 222q. Here, an ultrasound application device 240 for applying ultrasound to organic solvent C is provided between nozzle 220 and pump 222q, which is located closer to the nozzle in solvent circulation line 222. Ultrasound application device 240 is provided with, for example, an ultrasonic oscillator element. In enclosed cleaning chamber 210, a cleaning cup 212 is provided. In cleaning cup 212, a stage 214 is provided for holding and rotating wafer 50 on which a via hole and an insulating layer are formed. Cleaning cup 212 further has a solvent recovery port 216 for recovering a used solvent. In enclosed cleaning chamber 210, a static eliminating device 218 such as a discharge device, a soft X-ray radiation device, an ionizer, and an ultraviolet-ray radiation device is further provided. Enclosed cleaning chamber 210 further includes a dew condensation prevention gas line 234 for supplying dew condensation prevention gas AG to itself.

With reference to FIG. 20, the single-wafer, nozzle injection-type, ultrasonic cleaning in the present embodiment is performed, for example, as follows. Initially, wafer 50 on which a via hole and an insulating layer are formed, which is obtained after completion of step (D), is fixed onto stage 214 and rotated. Organic solvent C to which ultrasound application device 240 has applied ultrasound is supplied to nozzle 220, and organic solvent C to which ultrasound is applied is sprayed through nozzle 220 onto the surface of each of the via hole and the insulating layer of wafer 50. Contaminants adhering to the surface of each of the via hole and the insulating layer by step (D) and the like are thereby removed.

Here, used organic solvent C in enclosed cleaning chamber 210 is recovered from solvent recovery port 216 in cleaning cup 212 to solvent tank 226. Organic solvent C recovered in solvent tank 226 is refined in solvent refining unit 228 by removing contaminants. Refined organic solvent C is further filtered through filter 222f, supplied again to nozzle 220, and used for the next wafer cleaning.

If cleaning is performed with the wafer rotated, as in Embodiment 1B, electrification due to static electricity may occur as in Embodiment 1A. Therefore, it is preferable that static eliminating device 218 prevents the occurrence of electrification due to static electricity.

Further, as in Embodiment 1A, if organic solvent C is sprayed through nozzle 220, organic solvent C evaporates, and heat of vaporization of organic solvent C cools an inside of enclosed cleaning chamber 210. Dew condensation may occur thereby at the surface of each of the via hole and the insulating layer of wafer 50 and water may be generated. In such a case, if a pinhole is formed in the etching stopper film located at the bottom of the via hole, the underlying interconnection that contains copper may be subjected to corrosion.

To prevent dew condensation at the surface of each of the via hole and the insulating layer of wafer 50, it is preferable that dew condensation prevention gas AG is supplied to enclosed cleaning chamber 210. Here, the dew condensation prevention gas is not particularly limited as long as it can prevent dew condensation at the surface of each of the via hole and the insulating layer. A gas having a low dew point, such as dry air or a nitrogen gas, is preferably used. To prevent dew condensation, it is preferable that cleaning is performed in a nitrogen atmosphere in enclosed chamber 210 by purging at least any of dry air and a nitrogen gas.

Here, as in Embodiment 1A, organic solvent C used for the single-wafer, nozzle injection-type, ultrasonic cleaning as in Embodiment 1B is preferably a solvent that has a solubility of water of at most 2% by mass, a boiling point of at least 80° C., a vapor pressure of at most 0.01 MPa, heat of evaporation of at most 120 kJ/kg, a density of at least 1 g/cm³, a surface tension of at most 72.8 mN/m at 20° C. and at 1013 hPa, a solubility of gas higher than the solubility of water, and no flash point. In other words, as organic solvent C that has the properties (α1) to (α6) described above, HFE (hydrofluoroether) such as C₆F₁₃OCH₃ is preferably used in Embodiment 1B, as in Embodiment 1A.

Further, with reference to FIG. 20, organic solvent C preferably has a bubble-forming gas CG dissolved therein before ultrasound is applied thereto in Embodiment 1B. When ultrasound is applied to organic solvent C having bubble-forming gas CG dissolved therein, fine bubbles (cavitations) are formed in organic solvent C. With energy obtained when the fine bubbles impinge upon the surface of wafer 50 and disappear, removal of contaminants is promoted. Here, bubble-forming gas CG is preferably at least one gas selected from the group consisting of a hydrogen gas, a nitrogen gas, an oxygen gas, and a carbon dioxide gas, from a viewpoint of facilitate generation of fine bubbles by application of ultrasound. Further, from a viewpoint of increasing an amount of fine bubbles to be generated in organic solvent C by application of ultrasound, a dissolved molar concentration of fine bubble-forming gas CG in the organic solvent in the atmosphere is preferably at least 60% of a saturated molar concentration.

A method of allowing bubble-forming gas CG to be dissolved in organic solvent C before application of ultrasound is not particularly limited. As shown in FIG. 20, for example, it is possible to use the device in which bubble-forming gas line 224 for supplying bubble-forming gas CG is provided in solvent circulation line 222 at a position farther from nozzle 220 than the position where ultrasound application device 240 is provided.

In the description above, there has been described the single-wafer ultrasonic cleaning of a nozzle-injection type in which the organic solvent to which ultrasound is applied by the ultrasonic oscillator element attached to the nozzle is sprayed onto the substrate surface. However, it may also be possible to use a bar type in which a space between the substrate surface and a bar is filled with an organic solvent, and ultrasound is applied to the organic solvent by an ultrasonic oscillator element attached to the bar.

### Embodiment 1C

With reference to FIG. 21, step (E) in Embodiment 1 is preferably performed by ultrasonic immersion cleaning in which the surface of each of the via hole and the insulating layer is immersed in organic solvent C and ultrasound is applied thereto.

With reference to FIG. 21, an ultrasonic immersion cleaning device 300A for performing the above-described cleaning includes a cleaning bath 310, a heater 350 for heating an inside of the cleaning bath, and an ultrasound application device 340 for applying ultrasound to the inside of the cleaning bath. Ultrasound application device 340 is provided with, for example, an ultrasonic oscillator element. Further, cleaning bath 310 includes a solvent circulation line 322. Solvent circulation line 322 includes a solvent refilling line 322c, a filter 322f, and a pump 322p.

With reference to FIG. 21, the ultrasonic immersion cleaning in the present embodiment is performed, for example, as follows. Initially, wafer 50 on which a via hole and an insulating layer are formed, which is obtained after completion of step (D), is immersed in organic solvent C in cleaning bath 310. Here, a plurality of wafers 50 are preferably immersed at a time for effective cleaning.

Next, heater 350 heats organic solvent C to a prescribed temperature. Here, the temperature of organic solvent C is preferably raised to at least 40° C. After wafer 50 is lifted from organic solvent C, wafer 50 is cooled by heat of vaporization generated when organic solvent C evaporates from the surface of wafer 50, and at that time, if the temperature of organic solvent C is less than 40° C., dew condensation may occur at the surface of each of the via hole and the insulating layer of wafer 50 and water may be generated. In such a case, if a pinhole is formed in the etching stopper film located at the bottom of the via hole, the underlying interconnection that contains copper may be subjected to corrosion.

Next, ultrasound application device 340 applies ultrasound to organic solvent C in cleaning bath 310. The ultrasound applied to organic solvent C causes the surface of wafer 50 to oscillate. Contaminants adhering onto the surface of each of the via hole and the insulating layer of wafer 50 by step (D) are thereby removed.

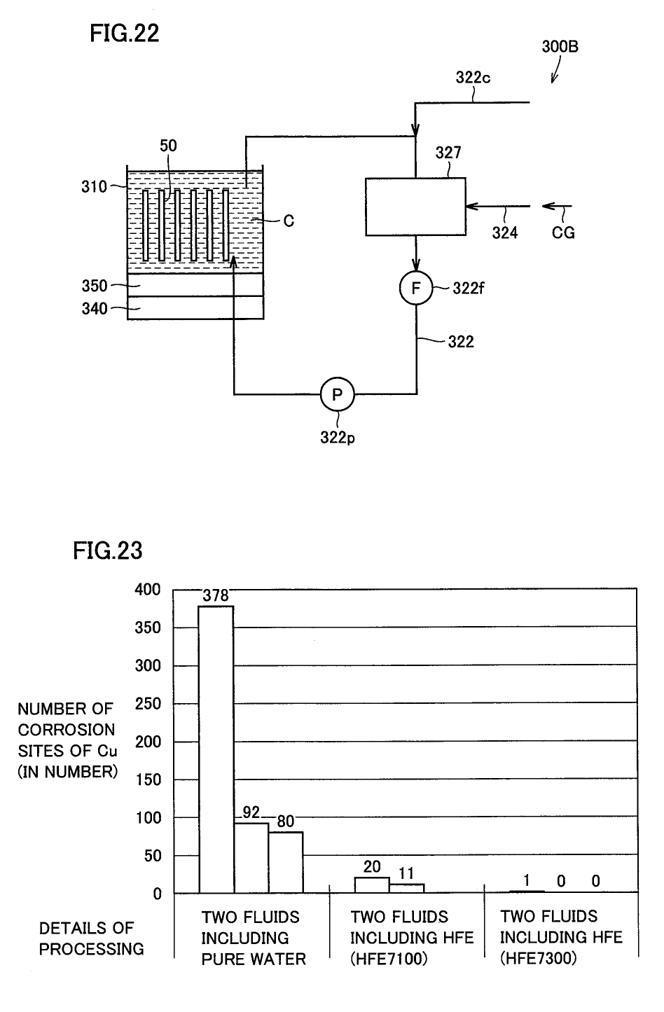

With reference to FIG. 22, in Embodiment 1C, bubble-forming gas CG is preferably dissolved in organic solvent C in which wafer 50 is immersed. If ultrasound is applied to organic solvent C having bubble-forming gas CG dissolved therein, fine bubbles (cavitations) are generated in organic solvent C. With energy obtained when the fine bubbles impinge upon the surface of wafer 50 and disappear, removal of contaminants from the surface of wafer 50 is promoted. Here, bubble-forming gas CG is preferably at least one gas selected from the group consisting of a hydrogen gas, a nitrogen gas, an oxygen gas, and a carbon dioxide gas, from a viewpoint of facilitating generation of fine bubbles by application of ultrasound.

Further, from a viewpoint of increasing an amount of fine bubbles to be generated in organic solvent C by application of ultrasound, a dissolved molar concentration of bubble-forming gas CG in organic solvent C in the atmosphere is preferably at least 60% of a saturated molar concentration.

A method of allowing bubble-forming gas CG to be dissolved in organic solvent C in which wafer 50 is to be immersed is not particularly limited. With reference to FIG. 22, for example, solvent circulation line 322 of an ultrasonic immersion cleaning device 300B includes, in addition to solvent refilling line 322c, filter 322f, and pump 322p, a bubble-forming gas dissolving unit 327 between a confluence of solvent circulation line 322 and solvent refilling line 322c, and filter 322f. Further, bubble-forming gas dissolving unit 327 includes a bubble-forming gas line 324 for supplying bubble-forming gas CG to organic solvent C. By using solvent circulation line 322 that includes such bubble-forming gas line 324 and bubble-forming gas dissolving unit 327, organic solvent C having bubble-forming gas CG dissolved therein can be provided in cleaning bath 310.

Wafer 50 on which a via hole and an insulating layer are formed, which is obtained after completion of step (D), is immersed in organic solvent C having the above-described bubble-forming gas CG dissolved therein. When ultrasound is applied to organic solvent C having bubble-forming gas CG dissolved therein, fine bubbles (cavitations) are generated in organic solvent C. With energy obtained when the fine bubbles impinge upon the surface of wafer 50 and disappear, removal of contaminants at the surface of each of the via hole and the insulating layer of wafer 50 is promoted. Here, from a viewpoint of facilitate generation of fine bubbles by application of ultrasound, bubble-forming gas CG is preferably at least one gas selected from the group consisting of a hydrogen gas, a nitrogen gas, an oxygen gas, and a carbon dioxide gas. Further, from a viewpoint of increasing an amount of fine bubbles to be generated in organic solvent C by application of ultrasound, a dissolved molar concentration of bubble-forming gas CG in organic solvent C in the atmosphere is preferably at least 60% of a saturated molar concentration. Here, a plurality of wafers 50 are preferably immersed at a time for efficient cleaning.

Next, heater 350 heats organic solvent C having bubble-forming gas CG dissolved therein, to a prescribed temperature. Here, as described above, the temperature of organic solvent C is preferably raised to at least 40° C.

Next, ultrasound application device 340 applies ultrasound to organic solvent C in cleaning bath 310, which organic solvent C having bubble-forming gas CG dissolved therein. Fine bubbles are thereby generated in organic solvent C. With energy obtained when the fine bubbles impinge upon the surface of wafer 50 and disappear, removal of contaminants at the surface of each of the via hole and the insulating layer of wafer 50 is promoted.

Here, organic solvent C used in the ultrasonic immersion cleaning as in Embodiment 1C is preferably a solvent that has a solubility of water of at most 2% by mass, a solubility of gas higher than the solubility of water, and no flash point. Each of the properties will now be described.

(β1) Organic solvent C having a solubility of water of at most 2% by mass is preferable. By using organic solvent C having a solubility of water of at most 2% by mass, it is possible to effectively suppress corrosion of the interconnection that contains copper.

(β2) Organic solvent C having a solubility of gas higher than the solubility of water is preferable. Higher concentration of bubble-forming gas CG dissolved in organic solvent C leads to increase in amount of fine bubbles to be generated by application of ultrasound, so that cleaning capacity is improved.

(β3) Organic solvent C having no flash point is preferable from a viewpoint of safety.

An example of organic solvent C that has the properties (β1) to (β3) described above includes HFE (hydrofluoroether) such as C₆F₁₃OCH₃.

### Second Embodiment

With reference to FIG. 1, a method of manufacturing a semiconductor device in the present embodiment further includes a step (H) of forming an interconnection groove at an upper portion of the via hole, and a step (E) (step (E2)) of cleaning the surface of each of the via hole, the interconnection groove, and the insulating layer with the organic solvent, between step (E) (step (E1)) and step (F) in Embodiment 1.

In other words, with reference to FIG. 1, the method of manufacturing a semiconductor device in Embodiment 2 includes step (A), step (B), step (C), step (D), step (E1), step (H), step (E2), step (F), and step (G).

Specifically, in the method of manufacturing the semiconductor device in Embodiment 2, step (A) (FIG. 2), step (B) (FIG. 3), step (C) (FIG. 4), step (D) (FIG. 5), and step (E1) (FIG. 6) are initially performed as in Embodiment 1.

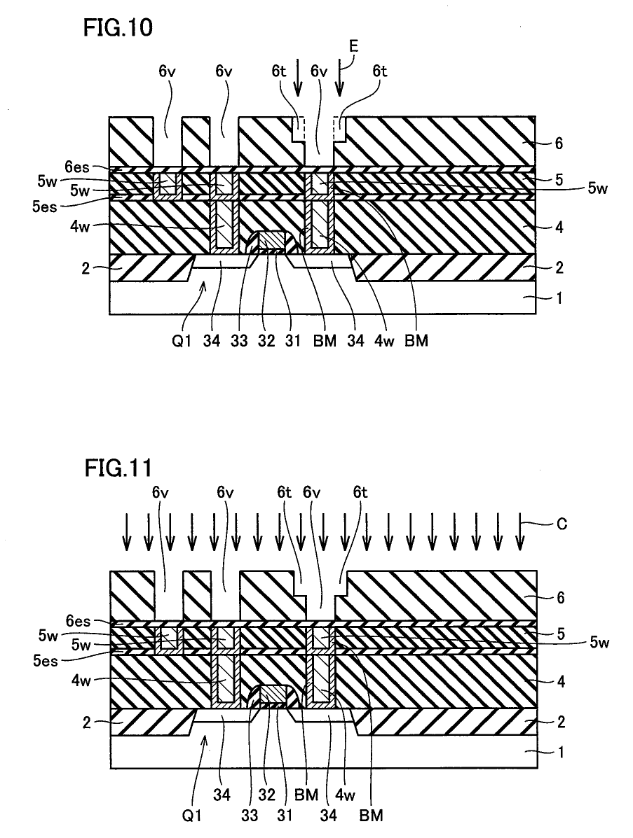

With reference to FIG. 10, after the above-described step (E1), an interconnection groove 6t that has a width larger than a width of via hole 6v is formed at an upper portion of via hole 6v (step (H)). A method of forming interconnection groove 6t is not particularly limited. However, from a viewpoint of facilitating formation of minute interconnection groove 6t, dry etching E is preferable.

With reference to FIG. 11, a surface of each of via hole 6v, interconnection groove 6t, and insulating layer 6 is cleaned with organic solvent C (step (E2)).

Organic solvent C is preferably hydrofluoroether. Particularly, organic solvent C is preferably HFE7100 (having a chemical formula of C₄F₉OCH₃, a boiling point of 61° C., and a solubility of water of 95 ppm (by mass)), HFE7200 (having a chemical formula of C₄F₉OC₂H₅, a boiling point of 76° C., and a solubility of water of 92 ppm (by mass)), or HFE7300 (having a chemical formula of C₆F₁₃OCH₃, a boiling point of 98° C., and a solubility of water of 67 ppm (by mass)), among hydrofluoroethers.

Further, the organic solvent is preferably a solvent that has a boiling point of at least 98° C., and preferably a solvent that has a solubility of water of at most 67 ppm by mass.

Accordingly, even if pinhole 6eh is formed in etching stopper film 6es during the above-described step (D) and/or step (E1), it is possible to clean the surface of each of via hole 6v, interconnection groove 6t, and insulating layer 6 in step (E2) without causing corrosion of interconnection 5w that contains copper and underlies etching stopper film 6es.

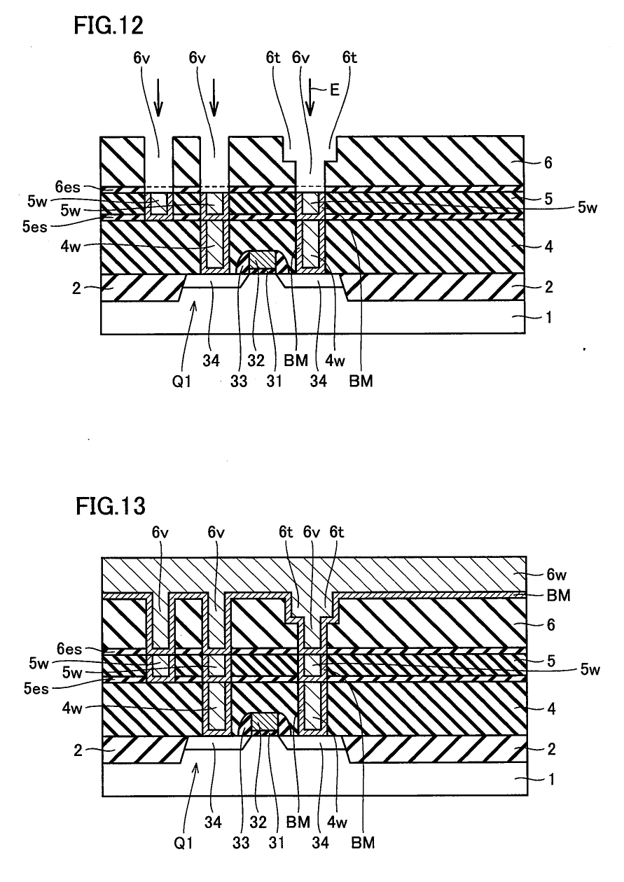

With reference to FIG. 12, etching stopper film 6es is removed such that interconnection 5w is exposed (step (F)). A method of removing etching stopper film 6es is not particularly limited. However, from a viewpoint of facilitating formation of minute via hole 6v, dry etching E is preferable.

With reference to FIG. 13, conductive layer 6w made of a material containing copper is formed on insulating layer 6 such that conductive layer 6w is embedded in via hole 6v and interconnection groove 6t by plating. Subsequently, conductive layer 6w is removed by a CMP method until the top surface of insulating layer 6 is exposed.

It is noted that from a viewpoint of suppressing migration of the interconnection, barrier metal layer BM is preferably formed between conductive layer 6w and insulating layer 6.

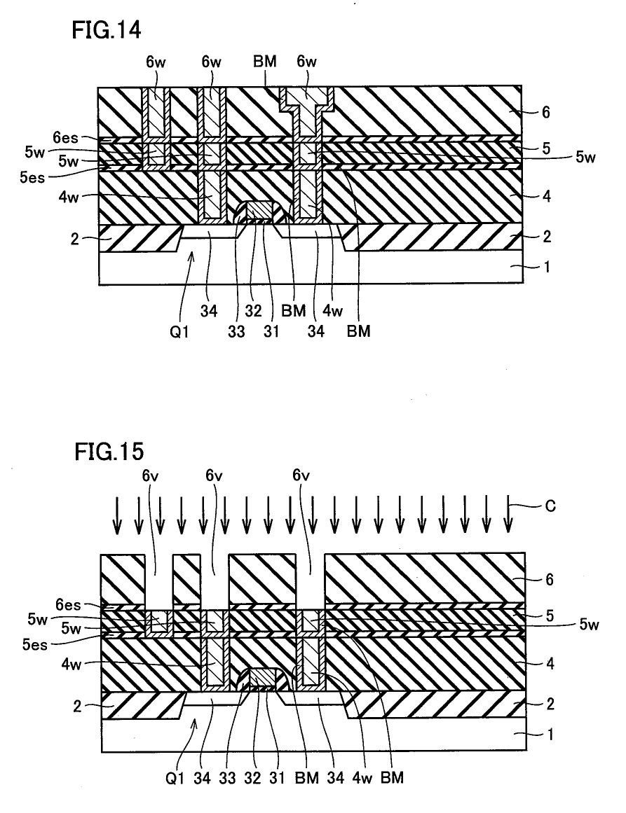

With reference to FIG. 14, by the above-described CMP method, conductive layer 6w remains in via hole 6v and interconnection groove 6t. Thereby, interconnection 6w that is electrically connected to interconnection 5w is formed from conductive layer 6w (step (G)).

As described above, the semiconductor device according to the present embodiment is manufactured.

The cleaning step with the use of an organic solvent in step (E1) and step (E2) in the present embodiment is not particularly limited. However, from a viewpoint of effectively removing contaminants adhering to the surface of each of insulating layer 6, via hole 6v, interconnection groove 6t, exposed interconnection 5w, and the like, the cleaning step can preferably be performed by the two-fluid jet cleaning as in Embodiment 1A described above, the single-wafer ultrasonic cleaning as in Embodiment 1B, or the ultrasonic immersion cleaning as in Embodiment 1C.

### Embodiment 3

With reference to FIG. 1, a method of manufacturing a semiconductor device in Embodiment 3 of the present invention includes step (A), step (B), step (C), step (D), step (H), step (E2), step (F), and step (G).

In other words, the method of manufacturing the semiconductor device in Embodiment 3 is the same as the method of manufacturing the semiconductor device in Embodiment 2, except that step (E1) is eliminated therefrom. By eliminating step (E1), it is possible to reduce manufacturing cost of the semiconductor device. Further, even if step (E1) is eliminated, it is possible to remove, by step (E2), contaminants adhering to the surface of each of via hole 6v, interconnection groove 6t, and insulating layer 6 by step (D) and step (H). Here, in Embodiment 3 as well, even if pinhole 6eh that reaches interconnection 5w underlying etching stopper film 6es is formed in etching stopper film 6es during step (D), it is possible to clean the surface of each of via hole 6v, interconnection groove 6t, and insulating layer 6 in step (E2) without causing corrosion of interconnection 5w that contains copper and underlies etching stopper film 6es, as in Embodiment 2.

Here, the cleaning step with the use of an organic solvent in step (E2) in Embodiment 3 is not particularly limited. However, from a viewpoint of effectively removing contaminants adhering to the surface of each of insulating layer 6, via hole 6v, interconnection groove 6t, exposed interconnection 5w, and the like, the cleaning step can preferably be performed by the two-fluid jet cleaning as in Embodiment 1A, the single-wafer ultrasonic cleaning as in Embodiment 1B, or the ultrasonic immersion cleaning as in Embodiment 1C.

As such, the step of cleaning the surface of each of via hole 6v and insulating layer 6 with the organic solvent (step (E)) may be performed at least any of before and after the step of forming interconnection groove 6t (step (H)). In other words, the step of cleaning the surface of each of via hole 6v and insulating layer 6 with the organic solvent (step (E)) may be performed only before the formation of interconnection groove 6t (as in step (E1)), may be performed only after the formation of interconnection groove 6t (as in step (E2)), or may be performed both of before and after the formation of interconnection groove 6t (as in step (E1) and step (E2)).

### Embodiment 4

With reference to FIG. 1 and FIG. 15, a method of manufacturing a semiconductor device in Embodiment 4 of the present invention further includes a step (J) (step (J1)) of cleaning the surface of each of exposed interconnection 5w, via hole 6v, and insulating layer 6 with organic solvent C, between step (F) and step (G) in Embodiment 1.

In other words, with reference to FIG. 1, the method of manufacturing the semiconductor device in Embodiment 4 includes step (A), step (B), step (C), step (D), step (E1), step (F), step (J1), and step (G).

By performing step (J1) after step (F), it is possible to remove contaminants adhering by step (F) to the surface of each of exposed interconnection 5w, via hole 6v, and insulating layer 6 with organic solvent C, without causing corrosion of interconnection 5w that contains copper.

Organic solvent C is preferably hydrofluoroether. Particularly, organic solvent C is preferably HFE7100 (having a chemical formula of C₄F₉OCH₃, a boiling point of 61° C., and a solubility of water of 95 ppm (by mass)), HFE7200 (having a chemical formula of C₄F₉OC₂H₅, a boiling point of 76° C., and a solubility of water of 92 ppm (by mass)), or HFE7300 (having a chemical formula of C₆F₁₃OCH₃, a boiling point of 98° C., and a solubility of water of 67 ppm ((by mass)), among hydrofluoroethers.

Further, the organic solvent is preferably a solvent having a boiling point of at least 98° C., and preferably a solvent having a solubility of water of at most 67 ppm by mass.

Here, the cleaning step with the use of organic solvent C in step (E1) and step (J1) in Embodiment 4 is not particularly limited. However, from a viewpoint of effectively removing contaminants adhering to the surface of each of insulating layer 6, via hole 6v, exposed interconnection 5w, and the like, the cleaning step can preferably be performed by the two-fluid jet cleaning as in Embodiment 1A, the single-wafer ultrasonic cleaning as in Embodiment 1B, or the ultrasonic immersion cleaning as in Embodiment 1C.

### Embodiment 5

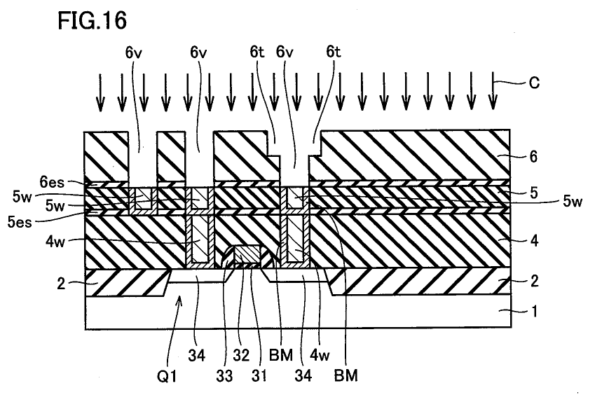

With reference to FIG. 1 and FIG. 16, a method of manufacturing a semiconductor device in Embodiment 5 of the present invention further includes a step (J) (step (J2)) of cleaning the surface of each of exposed interconnection 5w, via hole 6v, interconnection groove 6t, and insulating layer 6 with organic solvent C, between step (F) and step (G) in Embodiment 2.

In other words, with reference to FIG. 1, the method of manufacturing the semiconductor device in Embodiment 5 includes step (A), step (B), step (C), step (D), step (E1), step (H), step (E2), step (F), step (J2), and step (G).

By performing step (J2) after step (F), it is possible to remove contaminants adhering by step (F) to the surface of each of exposed interconnection 5w, via hole 6v, interconnection groove 6t, and insulating layer 6 by step (J2), without causing corrosion of underlying interconnection 5w that contains copper.

Organic solvent C is preferably hydrofluoroether. Particularly, organic solvent C is preferably HFE7100 (having a chemical formula of C₄F₉OCH₃, a boiling point of 61° C., a solubility of water of 95 ppm (by mass)), HFE7200 (having a chemical formula of C₄F₉OC₂H₅, a boiling point of 76° C., and a solubility of water of 92 ppm (by mass)), or HFE7300 (having a chemical formula of C₆F₁₃OCH₃, a boiling point of 98° C., and a solubility of water of 67 ppm (by mass)), among hydrofluoroethers.

Further, the organic solvent is preferably a solvent having a boiling point of at least 98° C., and preferably a solvent having a solubility of water of at most 67 ppm by mass.

Here, the cleaning step with the use of organic solvent C in step (E1), step (E2), and step (J2) in Embodiment 5 is not particularly limited. However, from a viewpoint of effectively removing contaminants adhering to the surface of each of insulating layer 6, via hole 6v, interconnection groove 6t, exposed interconnection 5w, and the like, the cleaning step can preferably be performed by the two-fluid jet cleaning as in Embodiment 1A, the single-wafer ultrasonic cleaning as in Embodiment 1B, or the ultrasonic immersion cleaning as in Embodiment 1C.

### Embodiment 6

With reference to FIG. 1 and FIG. 16, a method of manufacturing a semiconductor device in Embodiment 6 of the present invention further includes a step (J) (step (J2)) of cleaning the surface of each of exposed interconnection 5w, via hole 6v, interconnection groove 6t, and insulating layer 6 with organic solvent C, between step (F) and step (G) in Embodiment 3.

In other words, with reference to FIG. 1, the method of manufacturing the semiconductor device in Embodiment 6 includes step (A), step (B), step (C), step (D), step (H), step (E2), step (F), step (J2), and step (G).

By performing step (J2) after step (F), it is possible to remove contaminants adhering by step (F) to the surface of each of exposed interconnection 5w, via hole 6v, interconnection groove 6t, and insulating layer 6 by step (J2), without causing corrosion of underlying interconnection 5w that contains copper. Organic solvent C is preferably the same as the organic solvent described in Embodiment 5.

Here, the cleaning step with the use of organic solvent C in step (E2) and step (J2) in Embodiment 6 is not particularly limited. However, from a viewpoint of effectively removing contaminants adhering to the surface of each of insulating layer 6, via hole 6v, interconnection groove 6t, exposed interconnection 5w, and the like, the cleaning step can preferably be performed by the two-fluid jet cleaning as in Embodiment 1A, the single-wafer ultrasonic cleaning as in Embodiment 1B, or the ultrasonic immersion cleaning as in Embodiment 1C.

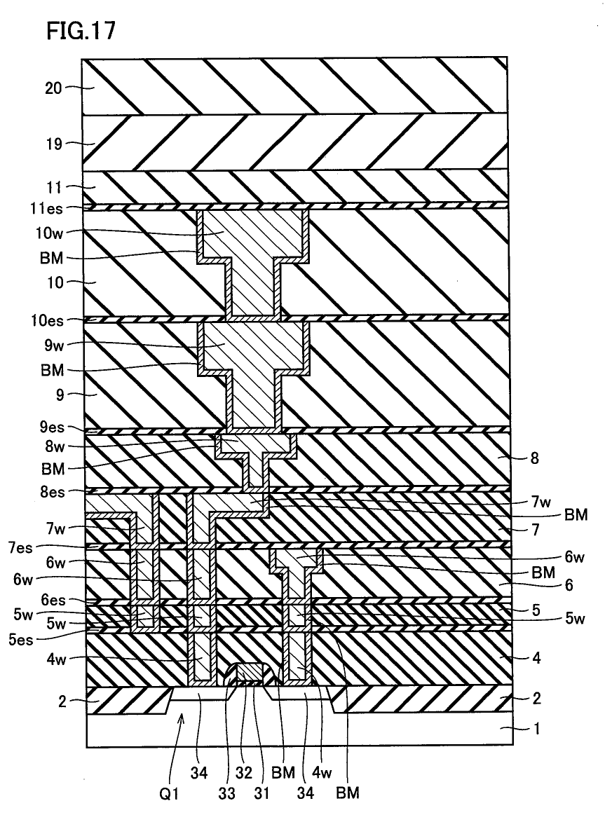

By further repeating step (B) to step (G) shown in FIG. 1 after step (G) in each of the manufacturing methods in Embodiment 1 to Embodiment 6 described above, a semiconductor device that has an interconnection with a multilayer structure can be obtained. Specifically, with reference to FIG. 17, a semiconductor device that has an interconnection with a multilayer structure can be obtained by performing, for example, the steps as described below.

Initially, an etching stopper film 7es is formed on the layer of interconnection 6w obtained after step (G) in Embodiment 5 (step (B)). Next, on etching stopper film 7es, an insulating layer 7 is formed (step (C)). Next, in insulating layer 7, a via hole that reaches etching stopper film 7es is formed (step (D)). Next, the surface of each of the via hole and the insulating layer 7 is cleaned with the organic solvent (step (E)). Next, an interconnection groove is formed at an upper portion of the via hole (step (H)). Next, the surface of each of the via hole, the interconnection groove, and insulating layer 7 is cleaned with the organic solvent (step (I)). Next, etching stopper film 7es is removed such that interconnection 6w is exposed (step (F)). Next, the surface of each of exposed interconnection 6w, the via hole, the interconnection groove, and insulating layer 7 is cleaned with the organic solvent (step (K)). Next, an interconnection 7w that electrically connects to exposed interconnection 6w is further formed (step (G)). With these steps, it is possible to form the layer of interconnection 7w located in etching stopper film 7es and insulating layer 7, on the layer of interconnection 6w located in etching stopper film 6es and insulating layer 6.

As such, by repeating the above-described steps, it is possible to form a layer of an interconnection 8w located in an etching stopper film 8es and an insulating layer 8, on the layer of interconnection 7w located in etching stopper film 7es and insulating layer 7. Further, it is possible to form a layer of an interconnection 9w located in an etching stopper film 9es and an insulating layer 9, on the layer of interconnection 8w located in etching stopper film 8es and insulating layer 8. Further it is possible to form a layer of an interconnection 10w located in an etching stopper film 10es and insulating layer 10, on the layer of interconnection 9w located in etching stopper film 9es and insulating layer 9. By doing so, it is possible to build a multilayer interconnection structure. It is noted that, to prevent migration of the interconnection, barrier metal layer BM is formed between the interconnection and the insulating layer in each of the layers.

Further, by forming an etching stopper film 11es on the layer of interconnection 10w, forming an insulating layer 11 on etching stopper film 11es, forming a passivation film 19 on insulating layer 11, and forming a polyimide film 20 on passivation film 19, it is possible to obtain a semiconductor device that has a multilayer interconnection structure and including MOS transistor Q1.

The present invention can particularly advantageously be applied to a method of manufacturing a semiconductor device, including a cleaning step after formation of a via hole.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a semiconductor device, comprising:
a step (A) of forming on a semiconductor substrate a first interconnection which contains copper;
a step (B) of forming an etching stopper film on said first interconnection;
a step (C) of forming an insulating layer on said etching stopper film;
a step (D) of forming in said insulating layer a via hole which reaches said etching stopper film;
a step (F) of removing said etching stopper film such that said via hole reaches said first interconnection and that said first interconnection is exposed through said via hole; and
a step (E) of cleaning a surface of each of said via hole and said insulating layer with an organic solvent before said step (F).

2. The method of manufacturing the semiconductor device according to claim 1, wherein said organic solvent is a solvent having a boiling point of at least 98° C.

3. The method of manufacturing the semiconductor device according to claim 1, wherein said organic solvent is a solvent having a solubility of water of at most 67 ppm by mass.

4. The method of manufacturing the semiconductor device according to claim 1, wherein said organic solvent is hydrofluoroether.

5. The method of manufacturing the semiconductor device according to claim 1, further comprising a step (H) of forming an interconnection groove at an upper portion of said via hole after said step (D) and before said step (F).

6. The method of manufacturing the semiconductor device according to claim 5, wherein said step (E) is performed at least any of before and after said step (H).

7. The method of manufacturing the semiconductor device according to claim 6, wherein said step (E) includes
a step (E1) of cleaning with said organic solvent before said step (H), and
a step (E2) of cleaning with said organic solvent after said step (H).

8. The method of manufacturing the semiconductor device according to claim 1, further comprising a step (J) of cleaning a surface of each of said exposed first interconnection, said via hole, and said insulating layer with the organic solvent after said step (F).

9. The method of manufacturing the semiconductor device according to claim 1, further comprising a step (G) of forming a second interconnection which electrically connects to said exposed first interconnection, after said step (F).

10. The method of manufacturing the semiconductor device according to claim 1, wherein said step (E) is performed by two-fluid jet cleaning in which said organic solvent and a spray gas are mixed at a nozzle and sprayed onto the surface of each of said via hole and said insulating layer.

11. The method of manufacturing the semiconductor device according to claim 10, wherein said organic solvent used in said cleaning has a solubility of water of at most 2% by mass, a boiling point of at least 80° C., a vapor pressure of at most 0.01 MPa, heat of evaporation of at most 120 kJ/kg, a density of at least 1 g/cm³, a surface tension of at most 72.8 mN/m at 20° C. and at 1013 hPa, a solubility of gas higher than the solubility of water, and no flash point.

12. The method of manufacturing the semiconductor device according to claim 10, wherein said cleaning is performed in a nitrogen atmosphere in an enclosed chamber by purging any of dry air and nitrogen.

13. The method of manufacturing the semiconductor device according to claim 1, wherein said step (E) is performed by single-wafer ultrasonic cleaning in which said organic solvent to which ultrasound is applied is used to clean the surface of each of said via hole and said insulating layer.

14. The method of manufacturing the semiconductor device according to claim 13, wherein said organic solvent used in said cleaning has a solubility of water of at most 2% by mass, a boiling point of at least 80° C., a vapor pressure of at most 0.01 MPa, heat of evaporation of at most 120 kJ/kg, a density of at least 1 g/cm³, a surface tension of at most 72.8 mN/m at 20° C. and at 1013 hPa, a solubility of gas higher than the solubility of water, and no flash point.

15. The method of manufacturing the semiconductor device according to claim 13, wherein said cleaning is performed in a nitrogen atmosphere in an enclosed chamber by purging any of dry air and nitrogen.

16. The method of manufacturing the semiconductor device according to claim 1, wherein said step (E) is performed by ultrasonic immersion cleaning in which the surface of each of said via hole and said insulating layer is immersed in said organic solvent and ultrasound is applied.

17. The method of manufacturing the semiconductor device according to claim 16, wherein said organic solvent used in said ultrasonic immersion cleaning has a solubility of water of at most 2% by mass, a solubility of gas higher than the solubility of water, and no flash point.

18. The method of manufacturing the semiconductor device according to claim 1, wherein a bubble-forming gas is dissolved in said organic solvent.

19. The method of manufacturing the semiconductor device according to claim 1, wherein said etching stopper film contains at least one material selected from the group consisting of SiCN, SiCO, SiC, and SiN.

20. The method of manufacturing the semiconductor device according to claim 1, wherein said insulating layer contains at least one Low-k material selected from the group consisting of TEOS, SiOF, and SiOC.
